(19) United States
(12) Patent Application Publication
(10) Pub. No.: US 2011/0180123 A1
(43) Pub. Date: Jul. 28, 2011

(54) SOLAR CELL MODULE AND METHOD OF MANUFACTURING THE SAME

(75) Inventors: Jung-Min Lee, Suwon-si (KR); Yun-Gi Kim, Yongin-si (KR); Dong-Kyun Kim, Suwon-si (KR)

(73) Assignee: SAMSUNG ELECTRONICS CO., LTD., Suwon-si (KR)

(21) Appl. No.: 12/855,257

(22) Filed: Aug. 12, 2010

(30) Foreign Application Priority Data
Jan. 28, 2010 (KR) 10-2010-0007950

(51) Int. Cl. H01L 31/042; H01L 31/04; H01L 31/18

(52) U.S. Cl. 136/244; 136/256; 156/278; 156/279; 977/762; 977/773

(57) ABSTRACT

A solar cell module includes a solar cell, a front protection plate disposed on a front side of the solar cell, and protrusions and depressions formed on a surface of the front protection plate, wherein the protrusions and depressions have a pitch equal to or less than a wavelength of visible light.

### CROSS-REFERENCE TO RELATED APPLICATION

This application claims priority to Korean Patent Application No. 10-2010-0007950, filed on Jan. 28, 2010, and all the benefits accruing therefrom under 35 U.S.C §119, the content of which in its entirety is herein incorporated by reference.

### BACKGROUND

1) Field

This disclosure relates to a solar cell module and a method of manufacturing the same.

2) Description of the Related Art

A solar cell is a photoelectric conversion device that converts photonic energy, such as solar energy, into electrical energy, and has been recognized as a renewable, non-polluting next generation energy source.

A solar cell typically includes a p-type semiconductor and an n-type semiconductor. If a photoactive layer absorbs photonic energy, e.g., solar energy, electron-hole pairs (“EHPs”) are produced in the semiconductor, and the produced electrons and holes move to the n-type semiconductor and the p-type semiconductor, respectively, and are collected in electrodes, and thus photonic energy may be converted to electrical energy.

A solar cell module typically includes a plurality of solar cells electrically connected, and a protection plate disposed on one side of the solar cell module.

It is beneficial that the solar cell module is required to effectively absorb incident light in order to increase efficiency of the solar cell module.

### SUMMARY

Therefore, in order to increase efficiency of a solar cell module, a reduction in light loss at the surface of the solar cell module is desirable.

One aspect of this disclosure provides a solar cell module that substantially reduces light loss at a surface of the solar cell module.

Another aspect of this disclosure provides a method of manufacturing the solar cell module.

According to one aspect of this disclosure, a solar cell module includes a solar cell; a front protection plate disposed on one side of the solar cell; and

protrusions and depressions formed on a surface of the front protection plate, wherein the protrusions and depressions have a pitch equal to or less than a wavelength of visible light.

The protrusions and depressions may have a width of about 30 nanometers (nm) to about 300 nm and a height of about 60 nm to about 400 nm.

The protrusions and depressions may include nanoparticles, nanowires, or combinations thereof. The protection plate may include a glass substrate.

The solar cell module may further include a rear protection plate disposed on the other opposite facing side of the solar cell.

According to another aspect of this disclosure, a method of manufacturing a solar cell module includes forming protrusions and depressions having a pitch equal to or less than a wavelength of visible light on a surface of a front protection plate, disposing the front protection plate on a solar cell, and assembling the solar cell and the front protection plate.

The forming of protrusions and depressions on the surface of the front protection plate may include disposing nanoparticles or growing nanowires on the surface of the front protection plate.

The forming of protrusions and depressions on the surface of the front protection plate may include disposing a hydrophobic material on the protection plate.

The forming of protrusions and depressions on the surface of the front protection plate may include providing a catalyst on the surface of the protection plate, resultantly growing nanowires.

The disposing the front protection plate on the solar cell may include laminating the solar cell and the front protection plate.

### BRIEF DESCRIPTION OF THE DRAWINGS

The above and other aspects, advantages and features of this disclosure will become more apparent by describing in further detail embodiments thereof with reference to the accompanying drawings, in which:

FIG. 1 is a cross-sectional view schematically showing an embodiment of a solar cell module;

FIG. 2 is a cross-sectional view schematically showing an embodiment of a front protection plate of the embodiment of a solar cell module of FIG. 1; and

FIG. 3 is a cross-sectional view schematically showing another embodiment of a front protection plate of the embodiment of a solar cell module of FIG. 1.

### DETAILED DESCRIPTION

The general inventive concept now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present invention will be described in further detail with reference to the accompanying drawings.

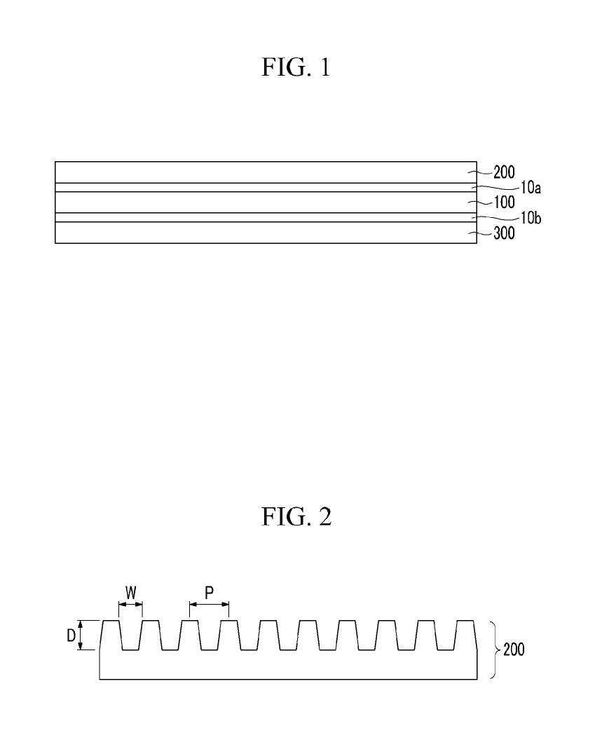

Referring to FIG. 1, an embodiment of a solar cell module is described in detail.

FIG. 1 is a cross-sectional view schematically showing the embodiment of a solar cell module.

Hereinafter, for better understanding and ease of description, a “front side” indicates a side receiving the solar energy in a solar cell 100, and a “rear side” indicates the other opposite facing side to the front side of the solar cell 100, but it will be noted that the use of these terms should not be interpreted as limiting the embodiments.

Referring to FIG. 1, the solar cell module according to one embodiment includes a solar cell 100, a front protection plate 200 disposed on the front side of the solar cell 100, and a rear protection plate 300 disposed on the rear side of the solar cell 100. Further, the solar cell module includes a filler 10a disposed between the solar cell 100 and the front protection plate 200 and a filler 10b disposed between the solar cell 100 and the rear protection plate 300.

The solar cell module may include a plurality of solar cells 100. The plurality of solar cells 100 may be arranged in a matrix shape and serially connected to each other, e.g., through an interconnector ribbon.

Each individual solar cell 100 may be a crystalline-type solar cell including a monocrystalline semiconductor material such as a silicon wafer, or a thin film-type solar cell including amorphous silicon semiconductor material.

The crystalline-type solar cell may include a p-type impurity doped semiconductor layer, an n-type impurity doped semiconductor layer, a first electrode electrically connected with the p-type impurity doped semiconductor layer, and a second electrode electrically connected with the n-type impurity doped semiconductor layer.

The thin film-type solar cell may include: a first electrode disposed on a substrate including glass, plastic, or metal or other materials with similar characteristics; a photoactive layer disposed on the first electrode and including a p-type impurity doped p-layer, an intrinsic semiconductor layer, and an n-type impurity doped n-layer; and a second electrode disposed on the photoactive layer.

The front protection plate 200 may include a material having high transparency and excellent mechanical strength such as tempered glass, for example, so as to protect the solar cell 100 from external impact.

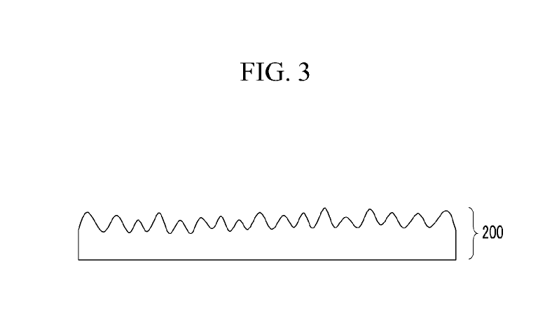

The front protection plate 200 is further explained with reference to FIG. 2 and FIG. 3.

FIG. 2 is a cross-sectional view schematically showing a front protection plate of the embodiment of a solar cell module of FIG. 1, and FIG. 3 is a cross-sectional view schematically showing a front protection plate of another embodiment of the solar cell module of FIG. 1.

Referring to FIG. 2, the front protection plate 200 according to one embodiment includes a plurality of regularly arranged protrusions and depressions, wherein the protrusions and depressions are recessed portions and convex portions, respectively, within the front protection plate 200. The protrusions and depressions may have a pitch (P) equal to or less than a wave length range of visible light. The protrusions and depressions may have a width (W) from about 30 nm to about 300 nm and a height (D) from about 60 nm to about 400 nm, for example.

As explained, the protrusions and depressions are arranged regularly on the surface of the front protection plate 200, resultantly reducing adhesion of foreign particles to reduce contamination. Thereby, deterioration of transparency due to foreign particles may be prevented, and a process of manually removing foreign particles may be reduced or effectively prevented, resultantly simplifying a manufacturing process of the solar cell 100 including the front protection plate 200.

Additionally, the protrusions and depressions may have a pitch (P) equal to or less than a wavelength of visible light, thereby preventing reflection and loss of visible light on the surface of the front protection plate, resultantly improving efficiency for absorbing visible light.

Alternative embodiments include configurations wherein the protrusions and depressions have a pitch (P) equal to or less than a wavelength of other regions of the electromagnetic spectrum, e.g., the infrared region or the ultraviolet region, in order to prevent reflection and loss of light in those wavelength regions.

The protrusions and depressions may include nanoparticles, nanowires, other similar nano-structures, or combinations thereof. The nanoparticles may be included on a surface of the front protection plate 200 by attaching the nanoparticles on the surface of the front protection plate 200, for example, and the nanowires may be formed, for example, by growing the nanowires on the surface of the front protection plate 200 using a catalyst.

As shown in FIG. 2, an area of the protrusions and depressions may decrease toward the top thereof. Furthermore, the protrusions and depressions may have a truncated circular cone shape with a blunt end, for example, but the shape of the protrusions and depressions is not limited thereto, and the shape thereof may be a circular cone shape with a sharp end or various other similar shapes.

Referring to FIG. 3, another embodiment of the front protection plate 200 includes a plurality of irregularly arranged protrusions and depressions, wherein the protrusions and depressions are recessed portions and convex portions, respectively, within the front protection plate 200. The protrusions and depressions may have a round end, and widths and heights thereof may be varied. However, on average, the protrusions and depressions may have a pitch (P) equal to or less than a wavelength of visible light. The protrusions and depressions may have an average width (W) of about 30 nm to about 300 nm and an average height (D) of about 60 nm to about 400 nm.

The rear protection plate 300 may be a reflector made of opaque metal, for example, and the rear protection plate 300 may prevent leakage of incident light therethrough and provide light reflected by the rear protection plate 300 back to the solar cell 100, thereby increasing efficiency for absorbing light. The rear protection plate 300 may include a material having high temperature resistance and high humidity resistance, and an excellent insulating property and durability, for example, silver (Ag), copper (Cu), aluminum (Al), nickel (Ni), titanium (Ti), alloys thereof, an opaque organic resin, other materials with similar characteristics or any combinations thereof.

Fillers 10a and 10b may be respectively disposed between the solar cell 100 and the front protection plate 200, and between the solar cell 100 and the rear protection plate 300. The fillers 10a and 10b may include a material that may prevent penetration of external moisture and oxygen and may be thermally cured, such as an ethylene vinyl acetate (“EVA”) film, for example, or other materials with similar characteristics.

An embodiment of a method of manufacturing method of the solar cell module will now be described in detail.

According to one embodiment, the method of manufacturing a solar cell module includes disposing protrusions and depressions having a pitch (P) equal to or less than a wavelength of visible light on the surface of a front protection plate 200, disposing the front protection plate 200 on the solar cell 100, and assembling the solar cell 100 and the front protection plate 200.

The forming of the protrusions and depressions on the surface of the front protection plate 200 may include disposing nanoparticles on the surface of the front protection plate 200 such as a glass plate. In one embodiment, the nanoparticles may have a spherical shape with a small size, but are not limited thereto.

The nanoparticles may be disposed on and adgered to the front protection plate 200 by various methods. The nanoparticles may be disposed by preparing a dispersion solution containing the nanoparticles dispersed in a solvent, for example, disposing the dispersion solution on the front protection plate 200, and removing the solvent.

The nanoparticles may be hydrophobic, for example, and the nanoparticles may include a fluorine-containing compound.

Further, the forming of the protrusions and depressions on the surface of the front protection plate 200 may include forming nanowires on the surface of the front protection plate 200 such as a glass plate.

The forming of the nanowires may include forming a catalyst on the front protection plate 200 and growing the nanowires using the catalyst.

The catalyst may be a metal catalyst such as nickel (Ni), iron (Fe), cobalt (Co), or alloys thereof, for example, or other materials having similar characteristics.

The growing of the nanowires may be conducted by disposing a hydrophobic material such as a fluorine containing compound by a solution process such as dipping or printing, or by deposition such as chemical vapor deposition (“CVD”), and annealing. As the hydrophobic material is adsorbed onto the surface of the catalyst by annealing, The nanowires grow in one direction by the action of the catalyst. A length and density of the nanowires can be controlled by process conditions.

Subsequently, the front protection plate 200 is disposed on the solar cell 100, and the solar cell 100 and the front protection plate 200 are assembled. The assembling may include laminating the solar cell 100 and the front protection plate 200.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A solar cell module comprising:
a solar cell;
a front protection plate disposed on a front side of the solar cell; and
protrusions and depressions formed on a surface of the front protection plate, wherein the protrusions and depressions have a pitch equal to or less than a wavelength of visible light.

2. The solar cell module of claim 1, wherein the protrusions and depressions have a width from about 30 nanometers to about 300 nanometers and a height from about 60 nanometers to about 400 nanometers.

3. The solar cell module of claim 1, wherein the protrusions and depressions comprise at least one of nanoparticles, nanowires, and combinations thereof.

4. The solar cell module of claim 1, wherein the protrusions and depressions have a decreasing cross-sectional area with distance from the surface of the front protection plate.

5. The solar cell module of claim 1, wherein the protection plate comprises a glass plate.

6. The solar cell module of claim 1, further comprising a rear protection plate disposed on a rear side of the solar cell.

7. The solar cell module of claim 1, further comprising a plurality of solar cells.

8. A method of manufacturing a solar cell module, the method comprising:
forming protrusions and depressions having a pitch equal to or less than a wavelength of visible light on a surface of a front protection plate; and
assembling the solar cell and the front protection plate by disposing the front protection plate on the solar cell.

9. The method of claim 8, wherein the forming of the protrusions and depressions on the surface of the front protection plate comprises:
at least one of disposing nanoparticles and growing nanowires on the surface of the front protection plate.

10. The method of claim 9, wherein the forming of the protrusions and depressions on the surface of the front protection plate comprises:
disposing a hydrophobic material on the front protection plate.

11. The method of claim 9, wherein the forming of the protrusions and depressions on the surface of the front protection plate comprises:
providing a catalyst on the surface of the front protection plate; and
growing nanowires using the catalyst.

12. The method of claim 8, wherein the assembling of the solar cell and the front protection plate comprises:
laminating the solar cell and the front protection plate.
